(19) United States
(12) Patent Application Publication
(10) Pub. No.: US 2024/0039301 A1
(43) Pub. Date: Feb. 1, 2024

(54) METHOD AND DEVICE FOR BALANCING A BATTERY STATE

(71) Applicant: SIMPLO TECHNOLOGY CO, LTD., Hsinchu County (TW)

(72) Inventor: Yi Ren GUO, Hsinchu City (TW)

(73) Assignee: SIMPLO TECHNOLOGY CO, LTD., Hsinchu County (TW)

(21) Appl. No.: 18/165,388

(22) Filed: Feb. 7, 2023

(30) Foreign Application Priority Data
Jul. 26, 2022 (TW) 111127973

(51) Int. Cl. H02J 7/00; G01R 31/3842

(52) U.S. Cl. CPC H02J 7/0016; H02J 7/0048; H02J 7/005; G01R 31/3842

(57) ABSTRACT

A method and a device for balancing a battery state are provided, in which the method includes executing a battery capacity balancing of a plurality of battery packs when voltage information of the plurality of battery packs is open circuit voltages or when balanced voltages of the plurality of battery packs are on the same curve fragment, such that balanced capacities of the plurality of battery packs can be calculated via aging voltage compensation parameters and/or aging capacity compensation parameters of the plurality of battery packs, and a capacity adjustment can be performed according to the balanced capacities. Therefore, the battery capacity balancing can be performed by obtaining voltages in different states, and the battery capacity of each battery pack can be accurately adjusted to achieve balance among the battery packs by taking the aging parameters of the battery packs into consideration.

### BACKGROUND

### 1. Technical Field

The present disclosure relates to a battery capacity balancing in the battery pack field, and more particularly, to a method and device for balancing a battery state.

### 2. Description of Related Art

As batteries are widely used in daily life, lithium-ion batteries have become a research topic of many teams in recent years. In order to improve the power or the working voltage supplied by the battery, a plurality of batteries must be combined in series to form a battery pack for use.

However, the self-discharge rate of each battery is different, and the battery internal resistance difference caused by the battery manufacturing tolerance, etc., makes the battery voltage to mismatch after a period of use. The cases mentioned above might lead some of the batteries in the battery pack overcharged, which can damage or even be dangerous to the batteries.

However, in the application of the lithium-ion battery pack of the prior art, the way to determine whether the states of the batteries are consistent is to evaluate the voltages of the batteries. For instance, if the voltages of the batteries are within a threshold, it is determined that the states of the batteries are similar. However, with this method, due to differences in internal resistance between the batteries, it is easy to misjudge the battery states are mismatched during the charging and discharging process of the battery.

Furthermore, there is no strong theoretical basis illustrating the threshold of this battery voltage difference (e.g., how much difference is required to represent a significant difference between the states of the batteries, and how to quantify the state difference between the batteries, etc.).

Therefore, how to optimize battery capacity balancing in the battery pack field that can reasonably evaluate the battery capacity of each battery pack and accurately adjust the battery capacity of each battery pack to achieve balance while taking the aging differences of each battery pack into consideration has become an urgent issue in the industry to be solved.

### SUMMARY

In order to solve the aforementioned conventional technical problems or provide related effects, the present disclosure provides a method for balancing a battery state, comprising: obtaining voltage information and current information of a plurality of battery packs; determining whether the obtained voltage information of the plurality of battery packs is open circuit voltages; determining whether balanced voltages calculated according to working voltages of the plurality of battery packs and aging voltage compensation parameters of the plurality of battery packs are all located on the same curve fragment when the voltage information of the plurality of battery packs is the working voltages; calculating balanced capacities of the plurality of battery packs via aging capacity compensation parameters of the plurality of battery packs when determining that the voltage information of the plurality of battery packs is the open circuit voltages, or when determining that the balanced voltages of the plurality of battery packs are all located on the same curve fragment; and calculating balanced capacity differences of the plurality of battery packs by using the balanced capacities of the plurality of battery packs, wherein capacities of the plurality of battery packs are adjusted according to the balanced capacity differences corresponding to the plurality of battery packs to balance battery capacities among the plurality of battery packs.

In the aforementioned embodiment, the method further comprises: obtaining available capacities corresponding to the open circuit voltages of the plurality of battery packs according to a State of Charge-Open Circuit Voltage (SoC-OCV) curve when determining that the voltage information of the plurality of battery packs is the open circuit voltages; and calculating balanced capacities of the plurality of battery packs by using the available capacities and the aging capacity compensation parameters of the plurality of battery packs.

In the aforementioned embodiment, the method further comprises: calculating the balanced voltages of the plurality of battery packs according to the working voltages, working currents of the current information, and the aging voltage compensation parameters of the plurality of battery packs when determining that the voltage information of the plurality of battery packs is the working voltages; determining whether the balanced voltages of the plurality of battery packs are on the same curve fragment in a State of Charge-Open Circuit Voltage (SoC-OCV) curve; obtaining available capacities corresponding to the balanced voltages of the plurality of battery packs according to the SoC-OCV curve when determining that the balanced voltages of the plurality of battery packs are all located on the same curve fragment; and calculating the balanced capacities of the plurality of battery packs by using the available capacities and the aging capacity compensation parameters of the plurality of battery packs.

In the aforementioned embodiment, the method further comprises: confirming whether there is previous voltage information and current information of the plurality of battery packs when the voltage information of the plurality of battery packs is the open circuit voltages; updating the aging voltage compensation parameters of the plurality of battery packs when confirming that there is the previous voltage information and current information of the plurality of battery packs; and updating the aging capacity compensation parameters of the plurality of battery packs after confirming that there is the previous voltage information of the plurality of battery packs.

In the aforementioned embodiment, the method further comprises a sub-method of updating the aging voltage compensation parameters of the plurality of battery packs, comprising: calculating working voltage differences of the plurality of battery packs according to the open circuit voltages and working voltages of the previous voltage information of the plurality of battery packs; and updating new aging voltage compensation parameters of the plurality of battery packs according to working currents of the previous current information and the working voltage differences of the previous voltage information of the plurality of battery packs.

In the aforementioned embodiment, the method further comprises a sub-method of updating the aging capacity compensation parameters of the plurality of battery packs, comprising: obtaining available capacities and working capacities of the plurality of battery packs via a State of Charge-Open Circuit Voltage (SoC-OCV) curve according to the open circuit voltages and working voltages of the previous voltage information of the plurality of battery packs; calculating working capacity differences of the plurality of battery packs by using the available capacities and the working capacities of the plurality of battery packs; and updating new aging capacity compensation parameters of the plurality of battery packs by using the working capacity differences of the plurality of battery packs.

In the aforementioned embodiment, the previous voltage information and current information of the plurality of battery packs are voltage information and current information of a last working current that is not 0 ampere before the open circuit voltages of voltage information of the plurality of battery packs are obtained.

The present disclosure further provides a device for balancing a battery state, comprising: a plurality of battery packs; a voltage measuring device and a current measuring device electrically connected to the plurality of battery packs to obtain voltage information and/or current information of the plurality of battery packs; a register communicatively connected to the voltage measuring device and the current measuring device to record the voltage information and/or the current information of the plurality of battery packs; and a processor communicatively connected to the register to execute the aforementioned method for balancing a battery state.

In the aforementioned embodiment, the plurality of battery packs are connected in series with each other, and each of the plurality of battery packs includes at least one cell.

In the aforementioned embodiment, the register stores a State of Charge-Open Circuit Voltage (SoC-OCV) curve corresponding to a cell type of the plurality of battery packs.

As can be seen from the above, in the method and device for balancing the battery state of the present disclosure, by determining whether the obtained voltage information of the plurality of battery packs is open circuit voltages, and thus battery capacity balancing is performed by determining that the voltage information of the plurality of battery packs is open circuit voltages or working voltages, and the balanced capacity difference of each battery pack is obtained according to the aging voltage compensation parameters and/or the aging capacity compensation parameters of the plurality of battery packs, so that the capacity of each battery pack is adjusted according to its balanced capacity difference, so as to achieve balance between the various battery packs.

### BRIEF DESCRIPTION OF THE DRAWINGS

FIG. 1A is a schematic view of a framework of a device for balancing a battery state according to the present disclosure.

FIG. 1B is a SoC-OCV curve of the battery packs in the device for balancing a battery state according to the present disclosure.

FIG. 2A is a flowchart illustrating a method of balancing the battery state according to the present disclosure.

FIG. 2B is a flowchart illustrating a first method for updating battery aging compensation parameters according to the present disclosure.

FIG. 2C is a flowchart illustrating a second method for updating battery aging compensation parameters according to the present disclosure.

FIG. 3A is a schematic view of voltage and current when the battery pack is charged and open-circuited in the device for balancing a battery state according to the present disclosure.

FIG. 3B is a schematic view of voltage and current when the battery pack is discharged and open-circuited in the device for balancing a battery state according to the present disclosure.

### DETAILED DESCRIPTIONS

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “one,” “a,” “first,” “second,” “on,” “above,” “below” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

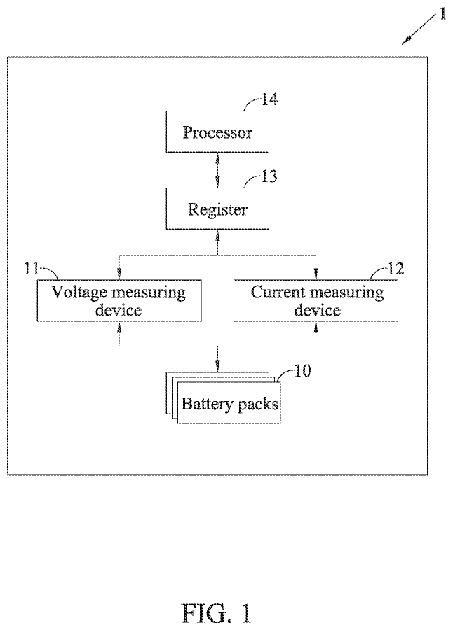

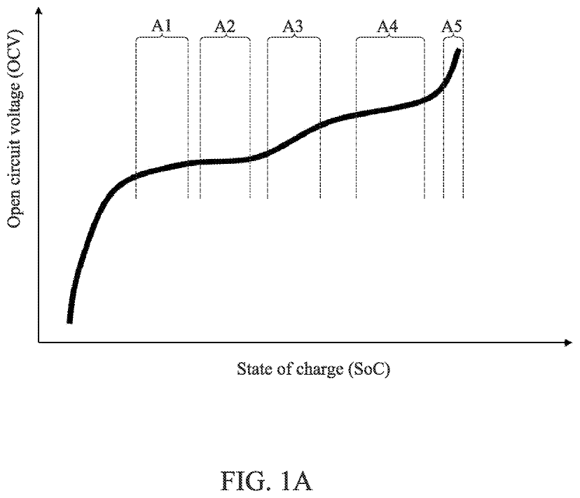

FIG. 1A is a schematic view of a framework of a device 1 for balancing a battery state according to the present disclosure. As shown in FIG. 1A, the device 1 for balancing a battery state includes: a plurality of battery packs 10 electrically connected to each other (such as in series), a voltage measuring device 11, a current measuring device 12, a register 13 and a processor 14.

Each of the battery packs 10 includes at least one cell (such as one or plural), wherein the cells included in the plurality of battery packs 10 can be nickel-cadmium batteries (Ni—Cd batteries), nickel-hydrogen batteries (Ni-MH batteries), or lithium ion batteries (Li-Ion batteries), etc., and the types of batteries in the plurality of battery packs 10 and the battery combinations thereof are not limited herein.

The voltage measuring device 11 and the current measuring device 12 are electrically connected to the plurality of battery packs 10 to obtain voltage information and current information of the plurality of battery packs 10. For instance, the voltage information of the plurality of battery packs 10 is voltage information (i.e., the open circuit voltages or the working voltages) of the plurality of battery packs 10 under open circuit or working condition measured by the voltage measuring device 11 after the voltage measuring device 11 is connected in parallel with the plurality of battery packs 10 respectively, and the current information of the plurality of battery packs 10 is current information (i.e., the working current) of the plurality of battery packs 10 under working condition measured by the current measuring device 12 after the current measuring device 12 is connected in series with the plurality of battery packs 10.

The register 13 is communicatively connected (or electrically connected) to the voltage measuring device 11 and the current measuring device 12 to record the voltage information and the current information of the plurality of battery packs 10 obtained by the voltage measuring device 11 and the current measuring device 12.

In one embodiment, as shown in FIG. 1B, the register 13 further stores a graph showing the relationship between State of Charge (SoC) and Open Circuit Voltage (OCV) corresponding to the cell types of the plurality of battery packs 10. It should be noted that the SoC-OCV curve is obtained via experiments or battery information (such as battery specification information) to obtain the open circuit voltage corresponding to the state of charge of the plurality of battery packs 10, wherein the relationship between the open circuit voltage and the state of charge is the characteristic of the battery cells of the plurality of battery packs 10, and the same type of the cell (or battery packs) has the same performance (outcome) showed in the SoC-OCV curve. In addition, a relationship table between the state of charge (SoC) and the open circuit voltage (OCV) can be established according to the SoC-OCV curve, and the relationship table also records the percentage of the state of charge (SoC) corresponding to the voltage of the open circuit voltage (OCV).

The processor 14 is communicatively connected (or electrically connected) to the register 13, and executes a battery balancing algorithm, so that the battery capacities of the plurality of battery packs 10 can be balanced when the battery capacities of the plurality of battery packs 10 are unbalanced (i.e., mismatched).

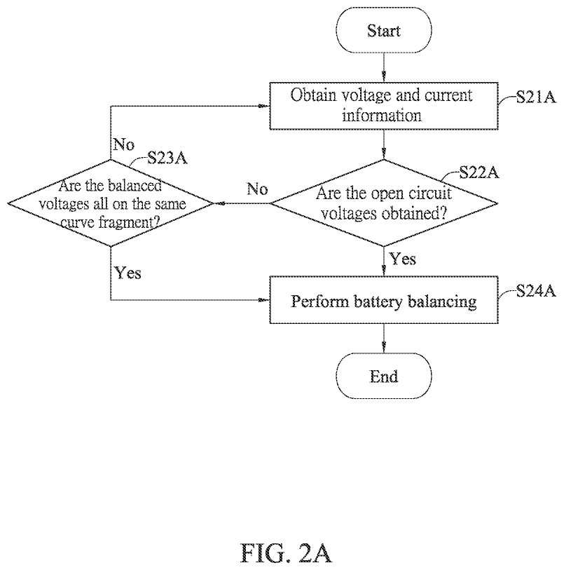

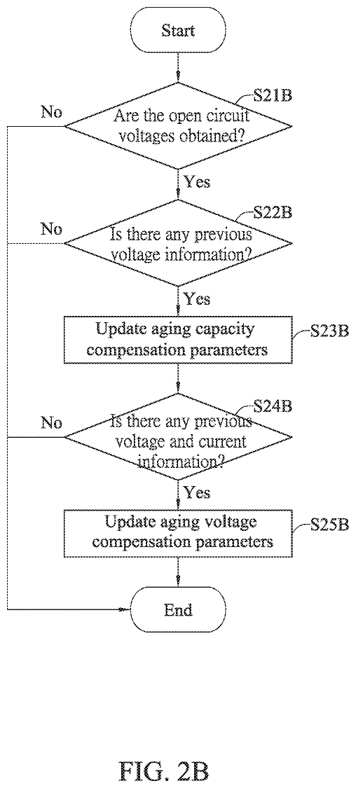

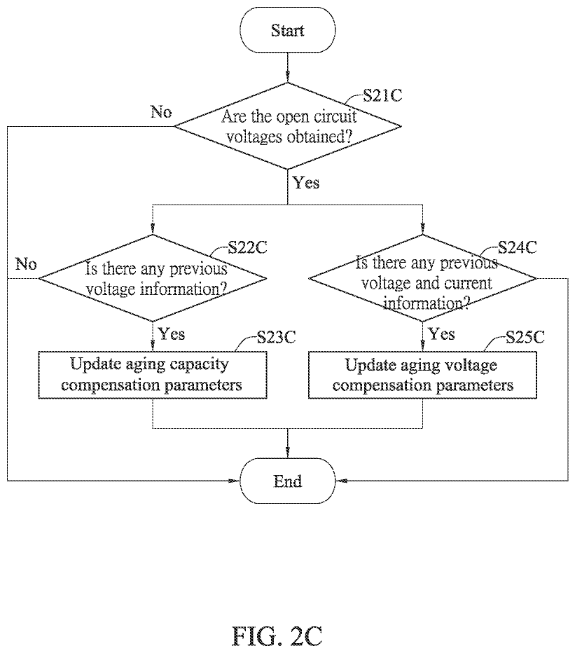

FIG. 2A is a flow chart illustrating a method of balancing the state of a battery according to the present disclosure. The method uses a battery balancing algorithm to balance the battery capacity, and is described with reference to FIG. 1A. The method includes the following steps S21A to S24A.

In step S21A, the processor 14 obtains the voltage information and/or the current information of the plurality of battery packs 10 from the register 13.

In step S22A, the processor 14 determines whether the obtained voltage information of the plurality of battery packs 10 is open circuit voltages, wherein if the voltage information of the plurality of battery packs 10 is the open circuit voltages, then step S24A is executed; otherwise, if the voltage information of the plurality of battery packs 10 is not the open circuit voltages (i.e., the voltage information of the plurality of battery packs 10 is the working voltages), then step 23A is executed.

In step S23A, when the voltage information of the plurality of battery packs 10 is the working voltages, the processor 14 determines whether the balanced voltages of the plurality of battery packs 10 are all located on the same curve fragment, wherein if the balanced voltages of the plurality of battery packs 10 are all located on the same curve fragment, then step S24A is executed; otherwise, if the balanced voltages of the plurality of battery packs 10 are not on the same curve fragment, then step S21A is executed, so that the processor 14 obtains the next voltage information and/or current information of the plurality of battery packs 10 from the register 13.

In step S24A, the processor 14 performs battery capacity balancing on the plurality of battery packs 10 to match the battery capacities among the plurality of battery packs 10.

In one embodiment, when the processor 14 determines that the voltage information of the plurality of battery packs 10 is open circuit voltages, the processor 14 performs battery capacity balancing according to the balanced capacity (Q_{Bal}ⁱ) (the calculation method of the balanced capacity (Q_{Bal}ⁱ) will be explained in the following first embodiment) obtained from the open circuit voltages of the plurality of battery packs 10.

In one embodiment, when the processor 14 determines that the voltage information of the plurality of battery packs 10 is working voltages, the processor 14 performs battery capacity balancing according to the balanced capacity (Q_{Bal}ⁱ) (the calculation method of the balanced capacity (Q_{Bal}ⁱ) will be explained in the following second embodiment) obtained from the working voltages of the plurality of battery packs 10.

FIG. 2B is a flow chart illustrating a first method of updating battery aging compensation parameter according to the present disclosure, and is described with reference to FIG. 1A. The first method includes the following steps S21B to S25B.

In step S21B, the processor 14 determines whether the obtained voltage information of the plurality of battery packs 10 is open circuit voltages, wherein if the voltage information of the plurality of battery packs 10 is the open circuit voltages, then step S22B is executed; otherwise, if the voltage information of the plurality of battery packs 10 is not the open circuit voltages, then the processor 14 ends the operation.

In step S22B, the processor 14 determines whether the register 13 stores the previous voltage information of the open circuit voltages of the plurality of battery packs 10, wherein if the previous voltage information is not stored in the register 13, then the processor 14 ends the operation; otherwise, if the previous voltage information is stored in the register 13, then step S23B is executed.

In step S23B, the aging capacity compensation parameters (Q_{Com}ⁱ) of the plurality of battery packs 10 are updated by the processor 14.

In step S24B, the processor 14 determines whether the register 13 stores the previous voltage information and current information of the open circuit voltages of the plurality of battery packs 10, wherein if the previous voltage information and current information are not stored in the register 13, then the processor 14 ends the operation; otherwise, if the previous voltage information and current information are stored in the register 13, then step S25B is executed. In one embodiment, the current of the previous current information is not 0 ampere.

In step S25B, the aging voltage compensation parameters (α_{com}ⁱ) of the plurality of battery packs 10 are updated by the processor 14.

FIG. 2C is a flow chart illustrating a second method for updating battery aging compensation parameter according to the present disclosure, and is described with reference to FIG. 1A. The second method includes the following steps S21C to S25C.

In step S21C, the processor 14 determines whether the obtained voltage information of the plurality of battery packs 10 is open circuit voltages, wherein if the voltage information of the plurality of battery packs 10 is the open circuit voltages, then step S22C and/or step S24C are executed; otherwise, if the voltage information of the plurality of battery packs 10 is not the open circuit voltages, then the processor 14 ends the operation.

In step S22C, the processor 14 determines whether the register 13 stores the previous voltage information of the open circuit voltages of the plurality of battery packs 10, wherein if the previous voltage information is not stored in the register 13, then the processor 14 ends the operation; otherwise, if the previous voltage information is stored in the register 13, then step S23C is executed.

In step S23C, the aging capacity compensation parameters (Q_{com}ⁱ) of the plurality of battery packs 10 are updated by the processor 14.

In step S24C, the processor 14 determines whether the register 13 stores the previous voltage information and current information of the open circuit voltages of the plurality of battery packs 10, wherein if the previous voltage information and current information are not stored in the register 13, then the processor 14 ends the operation; otherwise, if the previous voltage information and current information are stored in the register 13, then step S25C is executed. In one embodiment, the current of the previous current information is not 0 ampere.

In step S25C, the aging voltage compensation parameters (α_{com}ⁱ) of the plurality of battery packs 10 are updated by the processor 14.

The following are two implementation aspects of the processor of the device for balancing battery state of the present disclosure to perform battery capacity balancing, and are described with reference to FIG. 1A to FIG. 2C together. On the other hand, the contents of the two implementation aspects that are the same as those described above will not be repeated.

In the first embodiment, when the voltage information of the plurality of battery packs 10 obtained by the processor 14 from the register 13 is the open circuit voltages, the processor 14 obtains the percentage of the state of charge corresponding to the open circuit voltages of the plurality of battery packs 10 according to the SoC-OCV curve (as shown in FIG. 1), and then the design capacity of the plurality of battery packs 10 are multiplied by the percentage of the state of charge thereof to obtain the available capacities (Q_{OCV}ⁱ) of the plurality of battery packs 10.

Furthermore, the processor 14 uses a first formula (1) to calculate the balanced capacity (Q_{Bal}ⁱ) of the plurality of battery packs 10 according to the available capacities (Q_{OCV}ⁱ) and the aging capacity compensation parameters (Q_{Com}ⁱ) of the plurality of battery packs 10, and the first formula (1) is as follows:

Q_{Bal}ⁱ=Q_{OCV}ⁱ+Q_{Com}ⁱ (1)

Wherein i represents each of the plurality of battery packs 10; Q_{OCV}ⁱ is the available capacity of the plurality of battery packs 10; Q_{Com}ⁱ is the aging capacity compensation parameter of the plurality of battery packs 10; and Q_{Bal}ⁱ is the balanced capacity of the plurality of battery packs 10.

Afterwards, the processor 14 finds out the balanced capacity (Q_{Bal}ⁱ) which is the smallest from the balanced capacity (Q_{Bal}ⁱ) of the plurality of battery packs 10, so that the smallest of the balanced capacity (Q_{Bal}ⁱ) of the plurality of battery packs 10 is used as a comparison reference, and then a second formula (2) is used to calculate the balanced capacity differences (ΔQ_{Bal}ⁱ) of the plurality of battery packs 10, and the second formula (2) is as follows:

ΔQ_{Bal}ⁱ=Q_{Bal}ⁱ−min(Q_{Bal}ⁱ) (2)

Wherein i represents each of the plurality of battery packs 10; Q_{Bal}ⁱ are the balanced capacities of the plurality of battery packs 10; min(Q_{Bal}ⁱ) is the smallest of the balanced capacities of the plurality of battery packs 10; and ΔQ_{Bal}ⁱ are the balanced capacity differences of the plurality of battery packs 10.

In the second embodiment, when the voltage information of the plurality of battery packs 10 obtained by the processor 14 from the register 13 is the working voltages, the processor 14 uses a third formula (3) to calculate the balanced voltages (V_{Bal}ⁱ) of the plurality of battery packs 10 according to the working voltages, working currents and aging voltage compensation parameters (α_{com}ⁱ) of the plurality of battery packs 10, and the third formula (3) is as follows:

V_{Bal}ⁱ=V_{work}ⁱ−I_{work}×α_{com}ⁱ (3)

Wherein i represents each of the plurality of battery packs 10; V_{work}ⁱ are the working voltages of the plurality of battery packs 10; I_{work} is the working current of the plurality of battery packs 10; α_{com}ⁱ is the aging voltage compensation parameter of the plurality of battery packs 10; and V_{Bal}ⁱ is the balanced voltages of the plurality of battery packs 10.

Furthermore, when the processor 14 determines that the balanced voltages (V_{Bal}ⁱ) of the plurality of battery packs 10 are all located on the same curve fragment (such as one of the first curve fragment A1, the second curve fragment A2, the third curve fragment A3, the fourth curve fragment A4, or the fifth curve fragment A5) in the SoC-OCV curve (as shown in FIG. 1), the processor 14 obtains the percentage of the state of charge corresponding to the balanced voltages (V_{Bal}ⁱ) of the plurality of battery packs 10 according to the SoC-OCV curve (as shown in FIG. 1), and then the design capacity of the plurality of battery packs 10 are multiplied by the percentage of the state of charge thereof to obtain the available capacities (Q_{OCV}ⁱ) of the plurality of battery packs 10.

For instance, the processor 14 matches the balanced voltages (V_{Bal}ⁱ) of the plurality of battery packs 10 to the open circuit voltages corresponding to the values in the SoC-OCV curve (as shown in FIG. 1B) to determine whether the balanced voltages (V_{Bal}ⁱ) of the plurality of battery packs 10 are all located on the same curve fragment in the SoC-OCV curve (as shown in FIG. 1), and thereby the percentage of the state of charge of the plurality of battery packs 10 is obtained. It should be noted that, if any balanced voltage (V_{Bal}ⁱ) of the plurality of battery packs 10 is not on the same curve fragment as the balanced voltages (V_{Bal}ⁱ) of the other battery packs 10, then the processor 14 does not perform battery capacity balancing.

Then, the processor 14 uses the first formula (1) to calculate the balanced capacity (Q_{Bal}ⁱ) of the plurality of battery packs 10 according to the available capacities (Q_{OCV}ⁱ) and the aging capacity compensation parameters (Q_{Com}ⁱ) of the plurality of battery packs 10, and then the processor 14 finds out the balanced capacity (Q_{Bal}ⁱ) which is the smallest from the balanced capacity (Q_{Bal}ⁱ) of the plurality of battery packs 10, so that the smallest of the balanced capacity (Q_{Bal}ⁱ) of the plurality of battery packs 10 is used as a comparison reference, and the second formula (2) is used to calculate the balanced capacity differences (ΔQ_{Bal}ⁱ) of the plurality of battery packs 10.

Therefore, the processor 14 can use the open circuit voltages or the working voltages of the plurality of battery packs 10 to calculate the balanced capacity differences (ΔQ_{Bal}ⁱ) between the plurality of battery packs 10 and the battery pack 10 with the smallest balanced capacity, so that the processor 14 is made to adjust the capacities of the plurality of battery packs 10 according to the balanced capacity differences (ΔQ_{Bal}ⁱ) of the plurality of battery packs 10 so as to balance the capacities of the plurality of battery packs 10. For example, the capacity is adjusted by charging or discharging, so that the battery capacity among the plurality of battery packs 10 can be balanced. In another embodiment, the initial values of the aging voltage compensation parameters and the aging capacity compensation parameters of the plurality of battery packs 10 are preset to 0, or the initial values can be set according to requirements, and are not limited thereto.

The following is an implementation aspect of updating the aging voltage compensation parameter and the aging capacity compensation parameter of the present disclosure, and is described with reference to FIG. 1A to FIG. 2C together. On the other hand, the contents of the embodiment that are the same as those described above would not be repeated.

1. Update the Aging Voltage Compensation Parameters (α_{com}ⁱ)

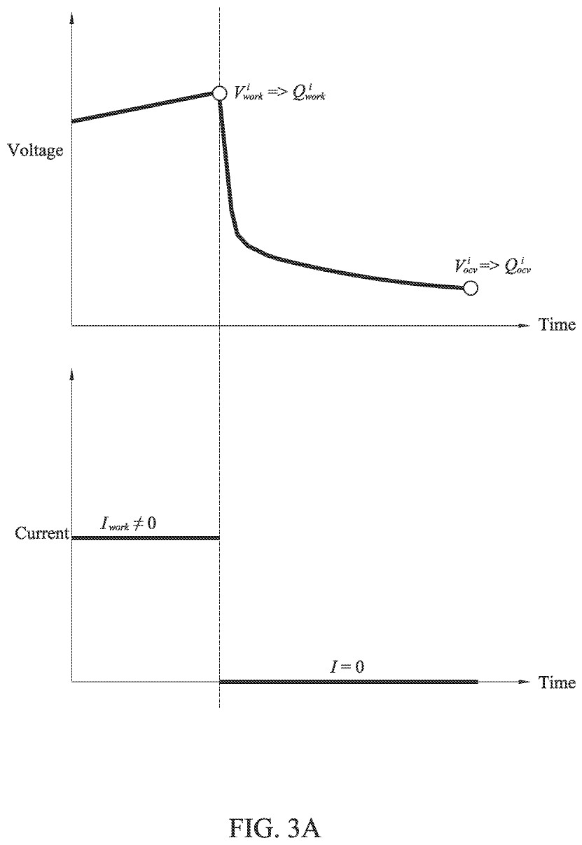

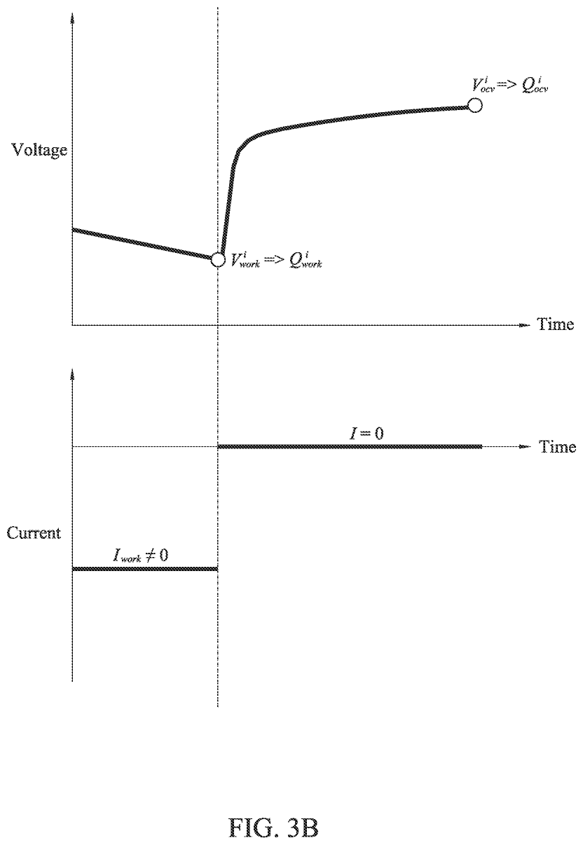

In an embodiment, as shown in FIG. 3A and FIG. 3B, the processor 14 obtains the previous voltage information and current information of the open circuit voltages (V_{OCV}ⁱ) of the plurality of battery packs 10 from the register 13, and the previous voltage information and current information are the voltage information and the current information of the last working current (I_{work}) that is not 0 ampere before the open circuit voltages (V_{OCV}ⁱ) of the plurality of battery packs 10 are obtained. For instance, as shown in FIG. 3A, the previous voltage information and current information are obtained when the plurality of battery packs 10 are charged, or as shown in FIG. 3B, the previous voltage information and current information are obtained when the plurality of battery packs 10 are discharged.

Furthermore, when updating the aging voltage compensation parameters (α_{com}ⁱ), the processor 14 firstly determines the open circuit voltages (V_{OCV}ⁱ) of the plurality of battery packs 10 and the working voltages (V_{work}ⁱ) of the previous voltage information, and then uses a fourth formula (4) to calculate the working voltage differences (ΔV_{work}ⁱ) of the plurality of battery packs 10, and the fourth formula (4) is as follows:

ΔV_{work}ⁱ=|V_{work}ⁱ−V_{OCV}ⁱ| (4)

Wherein i represents each of the plurality of battery packs 10; V_{OCV}ⁱ are the open circuit voltages of the plurality of battery packs 10; V_{work}ⁱ are the working voltages of the previous voltage information of the open circuit voltages of the plurality of battery packs 10; and ΔV_{work}ⁱ are the working voltage differences of the plurality of battery packs 10.

Finally, the processor 14 finds out the working voltage difference (ΔV_{work}ⁱ) which is the smallest from the working voltage differences (ΔV_{work}ⁱ) of the plurality of battery packs 10, so that the smallest of the working voltage differences (ΔV_{work}ⁱ) of the plurality of battery packs 10 is used as a comparison reference, and then based on the working current (I_{work}) of the plurality of battery packs 10, a fifth formula (5) is used to calculate a new aging voltage compensation parameters (α_{com}ⁱ) of the plurality of battery packs 10, and the fifth formula (5) is as follows:

$${α}_{com}^{i} = \frac{Δ {V}_{work}^{i} - min ( Δ {V}_{work}^{i} )}{{I}_{work}} \qquad ( 5 )$$

Wherein i represents each of the plurality of battery packs 10; ΔV_{work}ⁱ are the working voltage differences of the plurality of battery packs 10; min(ΔV_{work}ⁱ) is the smallest of the working voltage differences of the plurality of battery packs 10; I_{work} is the working current of the plurality of battery packs 10; and α_{com}ⁱ is the aging voltage compensation parameter.

2. Update the Aging Capacity Compensation Parameters (Q_{Com}ⁱ)

In an embodiment, as shown in FIG. 3A and FIG. 3B, the processor 14 obtains the previous voltage information and current information of the open circuit voltages (V_{OCV}ⁱ) of the plurality of battery packs 10 from the register 13, and the previous voltage information and current information are the voltage information and the current information of the last working current (I_{work}) that is not 0 ampere before the open circuit voltages (V_{OCV}ⁱ) of the plurality of battery packs 10 are obtained.

Furthermore, when updating the aging capacity compensation parameters (Q_{Com}ⁱ), the processor 14 first obtains the percentage of the state of charge of the working voltages (V_{work}ⁱ) of the previous voltage information of the plurality of battery packs 10 by using the SoC-OCV curve (as shown in FIG. 1), and then obtains the percentage of the state of charge of the open circuit voltages (V_{OCV}ⁱ) of the plurality of battery packs 10, so as to calculate the corresponding working capacity (Q_{work}ⁱ) and available capacity (Q_{OCV}ⁱ) respectively according to the design capacity of the plurality of battery packs 10.

In addition, according to the working capacity (Q_{work}ⁱ) and the available capacity (Q_{OCV}ⁱ) of the plurality of battery packs 10, the processor 14 uses a sixth formula (6) to calculate the working capacity difference (ΔQ_{work}ⁱ) of the plurality of battery packs 10, and the sixth formula (6) is as follows:

ΔQ_{work}ⁱ=|Q_{work}ⁱ−Q_{OCV}ⁱ| (6)

Wherein i represents each of the plurality of battery packs 10; Q_{work}ⁱ is the working capacity of the plurality of battery packs 10; Q_{OCV}ⁱ is the available capacity of the plurality of battery packs 10; and ΔQ_{work}ⁱ is the working capacity difference of the plurality of battery packs 10.

Finally, the processor 14 finds out the working capacity difference (ΔQ_{work}ⁱ) which is the smallest from the working capacity differences (ΔQ_{work}ⁱ) of the plurality of battery packs 10, so that the smallest of the working capacity differences (ΔQ_{work}ⁱ) of the plurality of battery packs 10 is used as a comparison reference, and then a seventh formula (7) is used to calculate the new aging capacity compensation parameters (Q_{Com}ⁱ) of the plurality of battery packs 10, and the seventh formula (7) is as follows:

Q_{Com}ⁱ=ΔQ_{work}ⁱ−min(ΔQ_{work}ⁱ) (7)

Wherein i represents each of the plurality of battery packs 10; Q_{Com}ⁱ is the aging capacity compensation parameter, and the aging capacity compensation parameter represents the aging degree difference of the plurality of battery packs 10, and its initial value is 0; ΔQ_{work}ⁱ is the working capacity difference of the plurality of battery packs 10; and min(ΔQ_{work}ⁱ) is the smallest of the working capacity differences of the plurality of battery packs 10.

In one embodiment, the processor 14 automatically updates the aging capacity compensation parameters (Q_{Com}ⁱ) during the use of the plurality of battery packs 10. Furthermore, when the aging capacity compensation parameters (Q_{Com}ⁱ) are updated, the processor 14 obtains the open circuit voltages (V_{OCV}ⁱ) of the plurality of battery packs 10. Therefore, the processor 14 is also triggered to determine whether the plurality of battery packs 10 have reached the balance of the battery capacity. If it is found that battery capacity balancing needs to be performed, the processor 14 can first perform battery capacity balancing for the plurality of battery packs 10, and then update the aging capacity compensation parameters (Q_{Com}ⁱ).

In one embodiment, the open circuit voltages (V_{OCV}ⁱ) of the plurality of battery packs 10 are the open circuit voltages (V_{OCV}ⁱ) when the plurality of battery packs 10 are fully charged or not fully charged. In a preferred embodiment, in order to make the updated aging capacity compensation parameters (Q_{Com}ⁱ) have the best accuracy, the best time to update is when the open circuit voltages (V_{OCV}ⁱ) of the fully charged battery packs 10 are obtained.

The following Embodiments 1 to 9 are practical application embodiments of the present disclosure, and are described with reference to FIG. 1A to FIG. 3B together. In addition, the contents of these Embodiments that are the same as those described above will not be repeated.

### Embodiment 1: A Method for Balancing the Battery Capacities of Two Battery Packs 10 Connected in Series Via their Open Circuit Voltages

In the embodiment, it is assumed that the SoC-OCV curve (as shown in FIG. 1B) of the two battery packs 10 is known, and the design capacity of the two battery packs 10 are both 4170 mAh, wherein the aging capacity compensation parameter (Q_{Com}¹) of the first battery pack in the two battery packs 10 is 52.0 mAh, and the aging capacity compensation parameter (Q_{Com}²) of the second battery pack in the two battery packs 10 is 0.0 mAh.

When the open circuit voltage (V_{OCV}¹) of the first battery pack is 4000 mV and the open circuit voltage (V_{OCV}²) of the second battery pack is 4100 mV, the processor 14 uses the SoC-OCV curve to obtain the percentage of the state of charge of the first battery pack of 65.2%, and the percentage of the state of charge of the second battery pack of 75.0%, and then multiplied by the design capacity of the two battery packs 10 (4170 mAh), so as to obtain that the available capacity (Q_{OCV}¹) of the first battery pack is 2718.8 mAh and the available capacity (Q_{OCV}²) of the second battery pack is 3127.5 mAh.

Next, the processor 14 utilizes the above-mentioned first formula (1) according to the aging capacity compensation parameters (Q_{Com}¹, Q_{Com}²) and the available capacities (Q_{OCV}¹, Q_{OCV}²) of the two battery packs 10, respectively, to calculate that the balanced capacity (Q_{Bal}¹) of the first battery pack is 2770.8 mAh, and the balanced capacity (Q_{Bal}²) of the second battery pack is 3127.5 mAh. Afterwards, the processor 14 uses the first battery pack with the smallest balanced capacity as a comparison reference, and then uses the above-mentioned second formula (2) to calculate that the balanced capacity difference (ΔQ_{Bal}¹) of the first battery pack is 0 mAh, and the balanced capacity difference (ΔQ_{Bal}²) of the second battery pack is 356.7 mAh.

From the above results, it can be seen that the second battery pack has a balanced capacity difference of 356.7 mAh more than the first battery pack. Therefore, self-discharge (that is, capacity adjustment) must be performed to reduce the available capacity of the second battery pack by 356.7 mAh, so that the two battery packs 10 achieve battery capacity balance (i.e., match). For example, the processor 14 sets the discharge current of a discharge circuit electrically connected to the second battery pack to 3 mA, so as to divide the balanced capacity difference (ΔQ_{Bal}²=356.7 mAh) of the second battery pack by the discharge current (3 mA), so that after the second battery pack is self-discharged for 118.9 hours, the first battery pack and the second battery pack can reach battery capacity balance.

In another embodiment, the processor 14 may also utilize a charging circuit to self-charge (i.e., capacity adjustment) the first battery pack, so as to increase the available capacity of the first battery pack by 356.7 mAh, so that the battery capacity balance between the two battery packs 10 is achieved.

### Embodiment 2: A Method for Balancing the Battery Capacities of Two Battery Packs 10 Connected in Series Via their Working Voltages and Working Currents

In the embodiment, it is assumed that the SoC-OCV curve (as shown in FIG. 1B) of the two battery packs 10 connected in series is known, and the design capacities of the two battery packs 10 are both 4170 mAh, wherein in the first battery pack of the two battery packs 10, the aging capacity compensation parameter (Q_{Com}¹) is 52.0 mAh and the aging voltage compensation parameter (α_{com}¹) is 0.05 V/A, and wherein in the second battery pack of the two battery packs 10, the aging capacity compensation parameter (Q_{Com}²) is 0.0 mAh, and the aging voltage compensation parameter (α_{com}²) is 0 V/A.

When the working voltage (V_{work}¹) of the first battery pack is 4025 mV, the working voltage (V_{work}²) of the second battery pack is 4100 mV, and the working current (I_{work}) flowing through the two battery packs 10 is a charging current of 500 mA, the processor 14 uses the above-mentioned third formula (3) to calculate that the balanced voltage (V_{Bal}¹) of the first battery pack is 4000 mV, and the balanced voltage (V_{Bal}²) of the second battery pack is 4100 mV. Then, the processor 14 determines whether the two battery packs 10 are located on the same curve fragment (such as one of the first curve fragment A1 to the fifth curve fragment A5) by using the SoC-OCV curve.

When the two battery packs 10 are located on the same curve fragment, the percentage, 65.2% of the state of charge of the first battery pack and the percentage, 75.0% of the state of charge of the second battery pack are obtained via the SoC-OCV curve, and then multiplied by the design capacities of the two battery packs (4170 mAh), so as to obtain that the available capacity (Q_{OCV}¹) of the first battery pack is 2718.8 mAh and the available capacity (Q_{OCV}²) of the second battery pack is 3127.5 mAh.

Next, the processor 14 utilizes the above-mentioned first formula (1) to calculate that the balanced capacity (Q_{Bal}¹) of the first battery pack is 2770.8 mAh and the balanced capacity (Q_{Bal}²) of the second battery pack is 3127.5 mAh according to the aging capacity compensation parameters (Q_{Com}¹, Q_{Com}²) and the available capacities (Q_{OCV}¹, Q_{OCV}²) of the two battery packs 10. Afterwards, the processor 14 uses the first battery pack with the smallest balanced capacity as a comparison reference, and then uses the above-mentioned second formula (2) to calculate that the balanced capacity difference (ΔQ_{Bal}¹) of the first battery pack is 0 mAh and the balanced capacity difference (ΔQ_{Bal}²) of the second battery pack is 356.7 mAh.

From the above results, it can be seen that the second battery pack has a balanced capacity difference of 356.7 mAh more than the first battery pack, so capacity adjustment must be performed. Therefore, the processor 14 sets the discharge current of a discharge circuit electrically connected to the second battery pack to 3 mA, so as to divide the balanced capacity difference (ΔQ_{Bal}²=356.7 mAh) of the second battery pack by the discharge current (3 mA), so that after the second battery pack is self-discharged for 118.9 hours, the first battery pack and the second battery pack can reach battery capacity balance.

### Embodiment 3: A Method for Balancing the Battery Capacities of a Plurality of Battery Packs 10 (Such as Three Battery Packs) Connected in Series Via their Open Circuit Voltages

In the embodiment, it is assumed that the SoC-OCV curve (as shown in FIG. 1B) of the three battery packs 10 is known, and the design capacities of the three battery 10 packs 10 are all 4170 mAh, wherein the aging capacity compensation parameter (Q_{Com}¹) of the first battery pack in the three battery packs 10 is 52.0 mAh, the aging capacity compensation parameter (Q_{Com}²) of the second battery pack in the three battery packs 10 is 0.0 mAh, and the aging capacity compensation parameter (Q_{Com}³) of the third battery pack in the three battery packs 10 is 20.0 mAh.

When the open circuit voltage (V_{OCV}¹) of the first battery pack is 4000 mV, the open circuit voltage (V_{OCV}²) of the second battery pack is 4100 mV and the open circuit voltage (V_{OCV}³) of the third battery pack is 4050 mV, the processor 14 uses the SoC-OCV curve to obtain the percentage of the state of charge of the first battery pack of 65.2%, the percentage of the state of charge of the second battery pack of 75.0% and the percentage of the state of charge of the third battery pack of 70.0%, and then multiplied by the design capacities of the three battery packs 10 (4170 mAh), so as to obtain that the available capacity (Q_{OCV}¹) of the first battery pack is 2718.8 mAh, the available capacity (Q_{OCV}²) of the second battery pack is 3127.5 mAh and the available capacity (Q_{OCV}³) of the third battery pack is 2919 mAh.

Next, the processor 14 utilizes the above-mentioned first formula (1) to calculate that the balanced capacity (Q_{Bal}¹) of the first battery pack is 2770.8 mAh, the balanced capacity (Q_{Bal}²) of the second battery pack is 3127.5 mAh and the balanced capacity (Q_{Bal}³) of the third battery pack is 2939 mAh according to the aging capacity compensation parameters (Q_{Com}¹, Q_{Com}², Q_{Com}³) and the available capacities (Q_{OCV}¹, Q_{OCV}², Q_{OCV}³) of the three battery packs 10. Afterwards, the processor 14 uses the first battery pack with the smallest balanced capacity as a comparison reference, and then uses the above-mentioned second formula (2) to calculate that the balanced capacity difference (ΔQ_{Bal}¹) of the first battery pack is 0 mAh, the balanced capacity difference (ΔQ_{Bal}²) of the second battery pack is 356.7 mAh and the balanced capacity difference (ΔQ_{Bal}³) of the third battery pack is 168.2 mAh.

From the above results, it can be seen that there is a balanced capacity difference of 356.7 mAh between the second battery pack and the first battery pack, and there is a balanced capacity difference of 168.2 mAh between the third battery pack and the first battery pack, so capacity adjustment must be performed. Therefore, the processor 14 sets the discharge current of a discharge circuit electrically connected to the second battery pack and the third battery pack to 3 mA, so as to divide the balanced capacity difference (ΔQ_{Bal}²=356.7 mAh) of the second battery pack and the balanced capacity difference (ΔQ_{Bal}³=168.2 mAh) of the third battery pack respectively by the discharge current (3 mA), so that the second battery pack needs to be self-discharged for 118.9 hours and the third battery pack needs to be self-discharged for 56.1 hours, and thus the first battery pack to the third battery pack can reach battery capacity balance.

### Embodiment 4: A Method for Balancing the Battery Capacities of a Plurality of Battery Packs 10 (Such as Three Battery Packs) Connected in Series Via their Working Voltages and Working Currents

In the embodiment, it is assumed that the SoC-OCV curve (as shown in FIG. 1B) of the three battery packs 10 connected in series is known, and the design capacities of the three battery packs 10 are all 4170 mAh, wherein in the first battery pack of the three battery packs 10, the aging capacity compensation parameter (Q_{Com}¹) is 52.0 mAh and the aging voltage compensation parameter (α_{com}¹) is 0.05 V/A, wherein in the second battery pack of the three battery packs 10, the aging capacity compensation parameter (Q_{Com}²) is 0.0 mAh and the aging voltage compensation parameter (α_{com}²) is 0 V/A, and wherein in the third battery pack of the three battery packs 10, the aging capacity compensation parameter (Q_{Com}³) is 20.0 mAh and the aging voltage compensation parameter (α_{com}³) is 0.02 V/A.

When the working voltage (V_{work}¹) of the first battery pack is 4025 mV, the working voltage (V_{work}²) of the second battery pack is 4100 mV, the working voltage (V_{work}³) of the third battery pack is 4060 mV and the working current (I_{work}) flowing through the three battery packs 10 is a charging current of 500 mA, the processor 14 uses the above-mentioned third formula (3) to calculate that the balanced voltage (V_{Bal}¹) of the first battery pack is 4000 mV, the balanced voltage (V_{Bal}²) of the second battery pack is 4100 mV and the balanced voltage (V_{Bal}³) of the third battery pack is 4050 mV. Then, the processor 14 determines whether the three battery packs 10 are located on the same curve fragment (such as one of the first curve fragment A1 to the fifth curve fragment A5) by using the SoC-OCV curve.

When the three battery packs 10 are located on the same curve fragment, the percentage, 65.2% of the state of charge of the first battery pack, the percentage, 75.0% of the state of charge of the second battery pack and the percentage, 70.0% of the state of charge of the third battery pack are obtained via the SoC-OCV curve, and then multiplied by the design capacities of the three battery packs (4170 mAh), so as to obtain that the available capacity (Q_{OCV}¹) of the first battery pack is 2718.8 mAh, the available capacity (Q_{OCV}²) of the second battery pack is 3127.5 mAh and the available capacity (Q_{OCV}³) of the third battery pack is 2919 mAh.

Next, the processor 14 utilizes the above-mentioned first formula (1) to calculate that the balanced capacity (Q_{Bal}¹) of the first battery pack is 2770.8 mAh, the balanced capacity (Q_{Bal}²) of the second battery pack is 3127.5 mAh and the balanced capacity (Q_{Bal}³) of the third battery pack is 2939 mAh according to the aging capacity compensation parameters (Q_{Com}¹, Q_{Com}², Q_{Com}³) and the available capacities (Q_{OCV}¹, Q_{OCV}², Q_{OCV}³) of the three battery packs 10. Afterwards, the processor 14 uses the first battery pack with the smallest balanced capacity as a comparison reference, and then uses the above-mentioned second formula (2) to calculate that the balanced capacity difference (ΔQ_{Bal}¹) of the first battery pack is 0 mAh, the balanced capacity difference (ΔQ_{Bal}²) of the second battery pack is 356.7 mAh and the balanced capacity difference (ΔQ_{Bal}³) of the third battery pack is 168.2 mAh.

From the above results, it can be seen that there is a balanced capacity difference of 356.7 mAh between the second battery pack and the first battery pack, and there is a balanced capacity difference of 168.2 mAh between the third battery pack and the first battery pack, so capacity adjustment must be performed. Therefore, the processor 14 sets the discharge current of a discharge circuit electrically connected to the second battery pack and the third battery pack to 3 mA, so as to divide the balanced capacity difference (ΔQ_{Bal}²=356.7 mAh) of the second battery pack and the balanced capacity difference (ΔQ_{Bal}³=168.2 mAh) of the third battery pack respectively by the discharge current (3 mA), so that the second battery pack needs to be self-discharged for 118.9 hours and the third battery pack needs to be self-discharged for 56.1 hours, and thus the first battery pack to the third battery pack can reach battery capacity balance.

### Embodiment 5: A Method for Updating the Aging Capacity Compensation Parameters of Two Battery Packs 10 Connected in Series (Condition 1)

In the embodiment, it is assumed that the SoC-OCV curve (as shown in FIG. 1B) of the two battery packs 10 is known, and the design capacities of the two battery packs 10 are both 4170 mAh, wherein the aging capacity compensation parameter (Q_{Com}¹) of the first battery pack in the two battery packs 10 is 0.0 mAh, and the aging capacity compensation parameter (Q_{Com}²) of the second battery pack in the two battery packs 10 is 10.0 mAh.

Furthermore, the open circuit voltage (V_{OCV}¹) of the first battery pack after fully charged is 4350 mV, the corresponding available capacity (Q_{OCV}¹) is 4015.7 mAh, and the working voltage (V_{work}¹) of the first battery pack before fully charged is 4380 mV, and the corresponding working capacity (Q_{work}¹) is 4107.5 mAh; and the open circuit voltage (V_{OCV}¹) of the second battery pack after fully charged is 4340 mV, the corresponding available capacity (Q_{OCV}²) is 3986.5 mAh, and the working voltage (V_{work}²) of the second battery pack before fully charged is 4380 mV, and the corresponding working capacity (Q_{work}²) is 4107.5 mAh.

Next, the processor 14 determines that there is the previous voltage information of the two battery packs 10, that is, the working voltages (V_{work}¹, V_{work}²), so the processor 14 uses the sixth formula (6) above to calculate that the working capacity difference (ΔQ_{work}¹) of the first battery pack is 91.8 mAh and the working capacity difference (ΔQ_{work}²) of the second battery pack is 121.0 mAh. Then, the processor 14 uses the smallest working capacity difference (i.e., the first battery pack) between the working capacity differences (ΔQ_{Com}^{1,2}) of the two battery packs 10 as a comparison reference, so as to use the above seventh formula (7) to calculate that the new aging capacity compensation parameter (Q_{Com}^{1′}) of the first battery pack is 0 mAh and the new aging capacity compensation parameter (Q_{Com}^{2′}) of the second battery pack is 29.2 mAh.

After that, the processor 14 updates the original aging capacity compensation parameters (Q_{Com}¹, Q_{Com}²) of the two battery packs 10 to the new aging capacity compensation parameters (Q_{Com}^{1′}, Q_{Com}^{2′}) of the two battery packs 10, and the new aging capacity compensation parameters (Q_{Com}^{1′}, Q_{Com}^{2′}) are used in the subsequent battery capacity balancing operations, as used in Embodiment 1.

### Embodiment 6: A Method for Updating the Aging Capacity Compensation Parameters of Two Battery Packs 10 Connected in Series (Condition 2)

In the embodiment, it is assumed that the SoC-OCV curve (as shown in FIG. 1B) of the two battery packs 10 is known, and the design capacities of the two battery packs 10 are both 4170 mAh, wherein the aging capacity compensation parameter (Q_{Com}¹) of the first battery pack in the two battery packs 10 is 10.0 mAh, and the aging capacity compensation parameter (Q_{Com}²) of the second battery pack in the two battery packs 10 is 0.0 mAh.

Furthermore, the open circuit voltage (V_{OCV}¹) of the first battery pack after fully charged is 4350 mV, the corresponding available capacity (Q_{OCV}¹) is 4015.7 mAh, and the working voltage (V_{work}¹) of the first battery pack before fully charged is 4380 mV, and the corresponding working capacity (Q_{work}¹) is 4107.5 mAh; and the open circuit voltage (V_{OCV}²) of the second battery pack after fully charged is 4340 mV, the corresponding available capacity (Q_{OCV}²) is 3986.5 mAh, and the working voltage (V_{work}²) of the second battery pack before fully charged is 4365 mV, and the corresponding working capacity (Q_{work}²) is 4061.6 mAh.

Next, the processor 14 determines that there is the previous voltage information of the two battery packs 10 (i.e., the working voltages (V_{work}¹, V_{work}²)), so the processor 14 uses the sixth formula (6) above to calculate that the working capacity difference (ΔQ_{work}¹) of the first battery pack is 91.8 mAh and the working capacity difference (ΔQ_{work}²) of the second battery pack is 75.1 mAh. Then, the processor 14 uses the smallest working capacity difference (i.e., the second battery pack) between the working capacity differences (ΔQ_{work}¹, ΔQ_{work}²) of the two battery packs 10 as a comparison reference, so as to use the above seventh formula (7) to calculate that the new aging capacity compensation parameter (Q_{Com}^{1′}) of the first battery pack is 16.7 mAh and the new aging capacity compensation parameter (Q_{Com}^{2′}) of the second battery pack is 0 mAh.

After that, the processor 14 updates the original aging capacity compensation parameters (Q_{Com}¹, Q_{Com}²) of the two battery packs 10 to the new aging capacity compensation parameters (Q_{Com}^{1′}, Q_{Com}^{2′}) of the two battery packs 10, and the new aging capacity compensation parameters (Q_{Com}^{1′}, Q_{Com}^{2′}) are used in the subsequent battery capacity balancing operations, as used in Embodiment 1.

### Embodiment 7: A Method for Updating the Aging Capacity Compensation Parameters of a Plurality of (Such as Three) Battery Packs 10 Connected in Series

In the embodiment, it is assumed that the SoC-OCV curve (as shown in FIG. 1B) of the three battery packs 10 is known, and the design capacities of the three battery packs 10 are all 4170 mAh, wherein the aging capacity compensation parameter (Q_{Com}¹) of the first battery pack in the three battery packs 10 is 20.0 mAh, the aging capacity compensation parameter (Q_{Com}²) of the second battery pack in the three battery packs 10 is 10.0 mAh and the aging capacity compensation parameter (Q_{Com}³) of the third battery pack in the three battery packs 10 is 0.0 mAh.

Furthermore, the open circuit voltage (V_{OCV}¹) of the first battery pack after fully charged is 4350 mV, the corresponding available capacity (Q_{OCV}¹) is 4015.7 mAh, and the working voltage (V_{work}¹) of the first battery pack before fully charged is 4380 mV, and the corresponding working capacity (Q_{work}¹) is 4107.5 mAh; the open circuit voltage (V_{OCV}²) of the second battery pack after fully charged is 4340 mV, the corresponding available capacity (Q_{OCV}²) is 3986.5 mAh, and the working voltage (V_{work}²) of the second battery pack before fully charged is 4365 mV, and the corresponding working capacity (Q_{work}²) is 4061.6 mAh; and the open circuit voltage (V_{OCV}³) of the third battery pack after fully charged is 4350 mV, the corresponding available capacity (Q_{OCV}³) is 4015.7 mAh, and the working voltage (V_{work}³) of the third battery pack before fully charged is 4370 mV, and the corresponding working capacity (Q_{work}³) is 4078.3 mAh.

Next, the processor 14 determines that there is the previous voltage information of the three battery packs 10 (i.e., the working voltages (V_{work}¹, V_{work}², V_{work}³)), so the processor 14 uses the sixth formula (6) above to calculate that the working capacity difference (ΔQ_{work}¹) of the first battery pack is 91.8 mAh, the working capacity difference (ΔQ_{work}²) of the second battery pack is 75.1 mAh and the working capacity difference (ΔQ_{work}³) of the third battery pack is 62.6 mAh. Then, the processor 14 uses the smallest working capacity difference (i.e., the third battery pack) among the working capacity differences (ΔQ_{work}¹, ΔQ_{work}², ΔQ_{work}³) of the three battery packs 10 as a comparison reference, so as to use the above seventh formula (7) to calculate that the new aging capacity compensation parameter (Q_{Com}^{1′}) of the first battery pack is 29.2 mAh, the new aging capacity compensation parameter (Q_{Com}^{2′}) of the second battery pack is 12.5 mAh and the new aging capacity compensation parameter (Q_{Com}^{3′}) of the third battery pack is 0 mAh.

After that, the processor 14 updates the original aging capacity compensation parameters (Q_{Com}¹, Q_{Com}², Q_{Com}³) of the three battery packs 10 to the new aging capacity compensation parameters (Q_{Com}^{1′}, Q_{com}^{2′}, Q_{Com}^{3′}) of the three battery packs 10, and the new aging capacity compensation parameters (Q_{Com}^{1′}, Q_{com}^{2′}, Q_{Com}^{3′}) are used in the subsequent battery capacity balancing operations, as used in Embodiment 3.

### Embodiment 8: A Method for Updating the Aging Voltage Compensation Parameters of Two Battery Packs 10 Connected in Series

In the embodiment, it is assumed that the SoC-OCV curve (as shown in FIG. 1B) of the two battery packs 10 is known, wherein the open circuit voltage (V_{OCV}¹) of the first battery pack in the two battery packs 10 is obtained and is 4350 mV, and the open circuit voltage (V_{OCV}²) of the second battery pack in the two battery packs 10 is obtained and is 4340 mV.

Furthermore, the current information and the voltage information of the last working current (I_{work}) that is not 0 ampere before the open circuit voltages (V_{OCV}¹, V_{OCV}²) of the two battery packs 10 are obtained, wherein the working current (I_{work}) of the current information of the two battery packs 10 is a charging current of 200 mA, the working voltage (V_{work}¹) of the voltage information of the first battery pack is 4380 mV, and the working voltage (V_{work}²) of the voltage information of the second battery pack is 4360 mV.

Next, the processor 14 uses the above-mentioned fourth formula (4) to calculate that the working voltage difference (ΔV_{work}¹) of the first battery pack is 30 mV, and the working voltage difference (ΔV_{work}²) of the second battery pack is 20 mV. In addition, the processor 14 finds out the smallest working voltage difference (ΔV_{work}ⁱ) (i.e., the second battery pack) from the working voltage differences (ΔV_{work}¹, ΔV_{work}²) of the two battery packs 10, and then the processor 14 uses the above-mentioned fifth formula (5) to calculate that the aging voltage compensation parameter (α_{com}¹) of the first battery pack is 0.05 V/A and the aging voltage compensation parameter (α_{com}²) of the second battery pack is 0 V/A according to the working current (I_{work}=200 mA).

After that, the processor 14 updates the original aging voltage compensation parameters (α_{com}¹, α_{com}²) of the two battery packs 10 to the new aging voltage compensation parameters (α_{Com}^{1′}, α_{Com}^{2′}) of the two battery packs 10, and the new aging voltage compensation parameters (α_{Com}^{1′}, α_{Com}^{2′}) are used in the subsequent battery capacity balancing operations, as used in Embodiment 2.

### Embodiment 9: A Method for Updating the Aging Voltage Compensation Parameters of a Plurality of (Such as Three) Battery Packs 10 Connected in Series

In the embodiment, it is assumed that the SoC-OCV curve (as shown in FIG. 1B) of the three battery packs 10 connected in series is known, wherein the open circuit voltage (V_{OCV}¹) of the first battery pack in the three battery packs 10 is obtained in 4350 mV, the open circuit voltage (V_{OCV}²) of the second battery pack in the three battery packs 10 is obtained in 4340 mV, and the open circuit voltage (V_{OCV}³) of the third battery pack in the three battery packs 10 is obtained in 4350 mV.

Furthermore, the current information and the voltage information of the last working current (I_{work}) that is not 0 ampere before the open circuit voltages (V_{OCV}¹, V_{OCV}², V_{OCV}³) of the three battery packs 10 are obtained, wherein the working current (I_{work}) of the current information of the three battery packs 10 is a charging current of 200 mA, the working voltage (V_{work}¹) of the voltage information of the first battery pack is 4380 mV, the working voltage (V_{work}²) of the voltage information of the second battery pack is 4360 mV and the working voltage (V_{work}³) of the voltage information of the third battery pack is 4374 mV.

Next, the processor 14 uses the above-mentioned fourth formula (4) to calculate that the working voltage difference (ΔV_{work}¹) of the first battery pack is 30 mV, the working voltage difference (ΔV_{work}²) of the second battery pack is 20 mV and the working voltage difference (ΔV_{work}³) of the third battery pack is 24 mV. In addition, the processor 14 finds out the smallest working voltage difference (ΔV_{work}ⁱ) (i.e., the second battery pack) from the working voltage differences (ΔV_{work}¹, ΔV_{work}², ΔV_{work}³) of the three battery packs 10, and then the processor 14 uses the above-mentioned fifth formula (5) to calculate that the aging voltage compensation parameter (α_{com}¹) of the first battery pack is 0.05 V/A, the aging voltage compensation parameter (α_{com}²) of the second battery pack is 0 V/A and the aging voltage compensation parameter (α_{com}³) of the third battery pack is 0.02 V/A according to the working current (I_{work}=200 mA).

After that, the processor 14 updates the original aging voltage compensation parameters (α_{Com}¹, α_{Com}², α_{Com}³) of the three battery packs 10 to the new aging voltage compensation parameters (α_{Com}^{1′}, α_{Com}^{2′}, α_{Com}^{3′}) of the three battery packs 10, and the new aging voltage compensation parameters (α_{Com}^{1′}, α_{Com}^{2′}, α_{Com}^{3′}) are used in the subsequent battery capacity balancing operations, as used in Embodiment 4.

To sum up, in the method and device for balancing the battery state of the present disclosure, by determining whether the obtained voltage information of the plurality of battery packs is open circuit voltages, and thus battery capacity balancing is performed by determining that the voltage information of the plurality of battery packs is open circuit voltages or working voltages, and the balanced capacity difference of each battery pack is obtained according to the aging voltage compensation parameters and/or the aging capacity compensation parameters of the plurality of battery packs, so that the capacity of each battery pack is adjusted according to its balanced capacity difference. Therefore, compared with the prior art, the present disclosure can perform battery capacity balancing under the condition of obtaining the open circuit voltages or the working voltages, and further takes the aging parameters of the battery packs into consideration, and then accurately adjusts the battery capacity of each battery pack, so as to achieve balance between the various battery packs.

Therefore, the present disclosure further has the following technical features and effects thereof:
1. The present disclosure analyzes the relationship between the state of charge and the open circuit voltage of the battery pack, finds out the available capacity of each battery pack via the relationship between the obtained open circuit voltage (or the calculated balanced voltage) and the state of charge, and accurately determines whether the battery capacity of each battery pack matches via the available capacity and the aging capacity compensation parameter of each battery pack.
2. After determining whether the balanced voltage of each battery pack is on the same curve fragment in the SoC-OCV curve by considering the balanced voltage of each battery pack obtained from the aging voltage compensation parameter, the present disclosure can balance the battery capacity under the condition of obtaining the working voltage of each battery pack. Therefore, compared with the prior art, the present disclosure can also perform battery capacity balancing under the condition of obtaining the working voltage of each battery pack by considering the aging voltage compensation parameter of each battery pack and the curve fragment in which it is located, and the present disclosure is not limited to obtaining the open circuit voltage to perform battery capacity balancing.
3. The present disclosure will record the voltage information and current information of each battery pack to know the available capacity difference between each battery pack, and determine the state of the batteries very intuitively by quantifying the difference in battery state. In addition, the aging state of each battery pack (such as the aging voltage compensation parameter and the aging capacity compensation parameter) can be further known via the voltage information and current information and be automatically updated, so that the battery capacity can be accurately adjusted according to its aging state in the future.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A method for balancing a battery state, comprising:
obtaining voltage information and current information of a plurality of battery packs;
determining whether the obtained voltage information of the plurality of battery packs is open circuit voltages;
determining whether balanced voltages calculated according to working voltages of the plurality of battery packs and aging voltage compensation parameters of the plurality of battery packs are all located on the same curve fragment when the voltage information of the plurality of battery packs is the working voltages;
calculating balanced capacities of the plurality of battery packs via aging capacity compensation parameters of the plurality of battery packs when determining that the voltage information of the plurality of battery packs is the open circuit voltages, or when determining that the balanced voltages of the plurality of battery packs are all located on the same curve fragment; and
calculating balanced capacity differences of the plurality of battery packs by using the balanced capacities of the plurality of battery packs, wherein capacities of the plurality of battery packs are adjusted according to the balanced capacity differences corresponding to the plurality of battery packs to balance battery capacities among the plurality of battery packs.

2. The method of claim 1, further comprising:
obtaining available capacities corresponding to the open circuit voltages of the plurality of battery packs according to a State of Charge-Open Circuit Voltage (SoC-OCV) curve when determining that the voltage information of the plurality of battery packs is the open circuit voltages; and
calculating balanced capacities of the plurality of battery packs by using the available capacities and the aging capacity compensation parameters of the plurality of battery packs.

3. The method of claim 1, further comprising:
calculating the balanced voltages of the plurality of battery packs according to the working voltages, working currents of the current information, and the aging voltage compensation parameters of the plurality of battery packs when determining that the voltage information of the plurality of battery packs is the working voltages;
determining whether the balanced voltages of the plurality of battery packs are on the same curve fragment in a State of Charge-Open Circuit Voltage (SoC-OCV) curve;
obtaining available capacities corresponding to the balanced voltages of the plurality of battery packs according to the SoC-OCV curve when determining that the balanced voltages of the plurality of battery packs are all located on the same curve fragment; and
calculating the balanced capacities of the plurality of battery packs by using the available capacities and the aging capacity compensation parameters of the plurality of battery packs.

4. The method of claim 1, further comprising:
confirming whether there is previous voltage information and current information of the plurality of battery packs when the voltage information of the plurality of battery packs is the open circuit voltages;
updating the aging voltage compensation parameters of the plurality of battery packs when confirming that there is the previous voltage information and current information of the plurality of battery packs; and
updating the aging capacity compensation parameters of the plurality of battery packs after confirming that there is the previous voltage information of the plurality of battery packs.

5. The method of claim 4, further comprising a sub-method of updating the aging voltage compensation parameters of the plurality of battery packs, comprising:
calculating working voltage differences of the plurality of battery packs according to the open circuit voltages and working voltages of the previous voltage information of the plurality of battery packs; and
updating new aging voltage compensation parameters of the plurality of battery packs according to working currents of the previous current information and the working voltage differences of the previous voltage information of the plurality of battery packs.

6. The method of claim 4, further comprising a sub-method of updating the aging capacity compensation parameters of the plurality of battery packs, comprising:
obtaining available capacities and working capacities of the plurality of battery packs via a State of Charge-Open Circuit Voltage (SoC-OCV) curve according to the open circuit voltages and working voltages of the previous voltage information of the plurality of battery packs;
calculating working capacity differences of the plurality of battery packs by using the available capacities and the working capacities of the plurality of battery packs; and
updating new aging capacity compensation parameters of the plurality of battery packs by using the working capacity differences of the plurality of battery packs.

7. The method of claim 5, wherein the previous voltage information and current information of the plurality of battery packs are voltage information and current information of a last working current that is not 0 ampere before the open circuit voltages of voltage information of the plurality of battery packs are obtained.

8. The method of claim 6, wherein the previous voltage information and current information of the plurality of battery packs are voltage information and current information of a last working current that is not 0 ampere before the open circuit voltages of voltage information of the plurality of battery packs are obtained.

9. A device for balancing a battery state, comprising:
a plurality of battery packs;
a voltage measuring device and a current measuring device electrically connected to the plurality of battery packs to obtain voltage information and/or current information of the plurality of battery packs;
a register communicatively connected to the voltage measuring device and the current measuring device to record the voltage information and/or the current information of the plurality of battery packs; and
a processor communicatively connected to the register to execute the method of claim 1.

10. The device of claim 9, wherein the plurality of battery packs are connected in series with each other, and each of the plurality of battery packs includes at least one cell.

11. The device of claim 9, wherein the register stores a State of Charge-Open Circuit Voltage (SoC-OCV) curve corresponding to a cell type of the plurality of battery packs.
